(19) United States
(12) Patent Application Publication
(10) Pub. No.: US 2012/0069522 A1
(43) Pub. Date: Mar. 22, 2012

(54) THERMAL MODULE AND ELECTRONIC DEVICE INCORPORATING THE SAME

(75) Inventor: JUI-WEN HUNG, Tu-Cheng (TW)

(73) Assignee: FOXCONN TECHNOLOGY CO., LTD., Tu-Cheng (TW)

(21) Appl. No.: 12/916,633

(22) Filed: Oct. 31, 2010

(30) Foreign Application Priority Data
Sep. 21, 2010 (TW) 99132116

(51) Int. Cl. H05K 7/20; H05K 9/00

(52) U.S. Cl. 361/700; 361/818; 361/718

(57) ABSTRACT

An electronic device includes a circuit board and a thermal module mounted thereon. The circuit board has a heat-generating chip and an electromagnetic interference (EMI) source mounted thereon. The thermal module includes a shielding cover and a heat conducting member. The shielding cover is heat-conductive and electrically-conductive material, and defines a cavity therein. The shielding cover encloses the EMI source in the cavity for EMI shielding. The heat conducting member has one end thermally connecting with the shielding cover and another end thermally connecting with the heat-generating chip for transferring heat from the heat-generating chip to the shielding cover.

### BACKGROUND

1. Technical Field

The disclosure generally relates to a thermal module for dissipating heat generated by an electronic component such as a heat-generating chip, and an electronic device incorporating the thermal module.

2. Description of Related Art

In an electronic device such as a computer or a communication product, a thermal module is often used to dissipate heat from a component. The component is typically an electronic component, and may for example be a heat-generating chip such as a central processing unit (CPU). The thermal module includes a heat conducting member and a heat dissipation member. Heat generated by the heat-generating chip is transferred to the heat dissipation member via the heat conducting member. With trends toward miniaturization and light weight, however, the space available in the electronic device for accommodating the thermal module is limited.

What is needed, therefore, is a means to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead placed upon clearly illustrating the principles of the present embodiments. Moreover, in the drawings, like reference numerals designate corresponding parts throughout the views.

FIG. 1 is an isometric, assembled view of an electronic device in accordance with an exemplary embodiment of the present disclosure.

FIG. 2 is an exploded view of the electronic device of FIG. 1.

FIG. 3 is similar to FIG. 2, but viewed from a different aspect.

### DETAILED DESCRIPTION

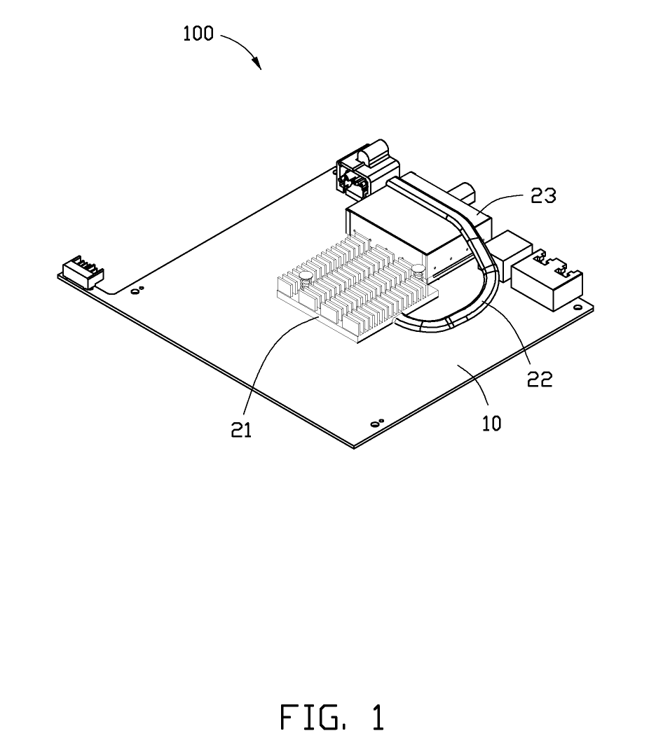

Referring to FIG. 1, an electronic device 100 according to an exemplary embodiment of the present disclosure is shown. The electronic device 100 includes a circuit board 10, and a thermal module 20 mounted on the circuit board 10.

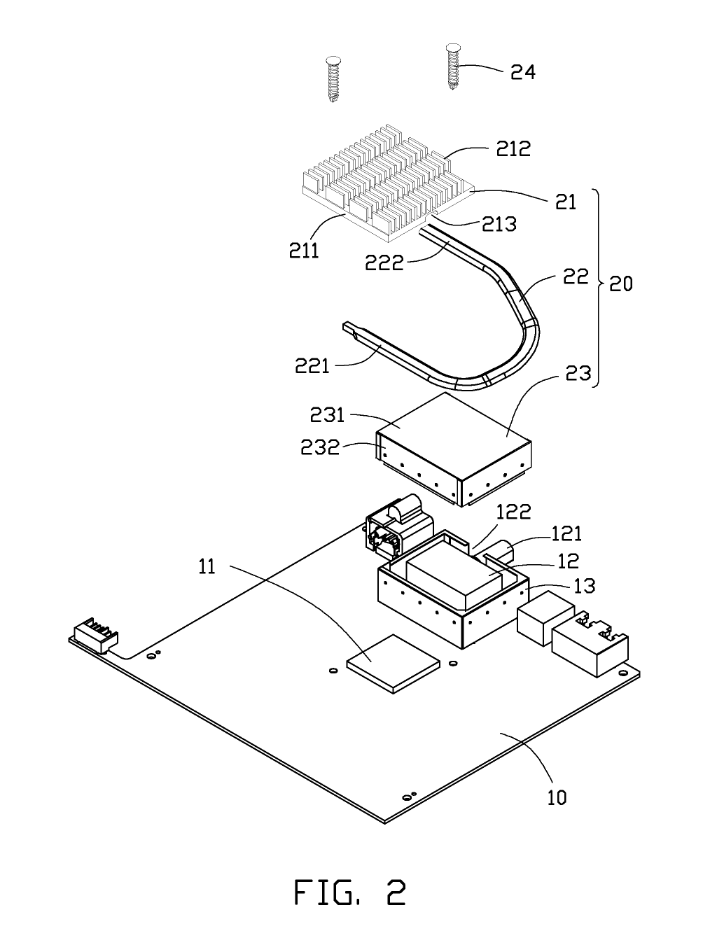

Referring also to FIG. 2, the circuit board 10 has a heat-generating chip 11 and an electromagnetic interference (EMI) source 12 mounted thereon. The heat-generating chip 11 is a main heat-generating member of the circuit board 10, and is located at a middle portion of the circuit board 10.

The EMI source 12 is located adjacent to an edge of the circuit board 10, apart from the heat-generating chip 11. The EMI source 12 can be any component capable of emitting electromagnetic waves when in use, such as pins of integrated circuits, cable connectors, cable sockets and other electronic components. In this embodiment, the EMI source 12 is a cable socket for electrically connecting a signal cable 121 such as a television (TV) signal cable with the circuit board 10. When the electronic device 100 is in operation, electromagnetic waves emitted by the EMI source 12 may interfere with other components on the circuit board 10, such as the heat-generating chip 11.

A mounting seat 13 is disposed around the EMI source 12. The mounting seat 13 is a hollow rectangular frame. The mounting seat 13 is fixed on the circuit board 10 and surrounds the EMI source 12. The mounting seat 13 defines an opening 122 through which the signal cable 121 extends.

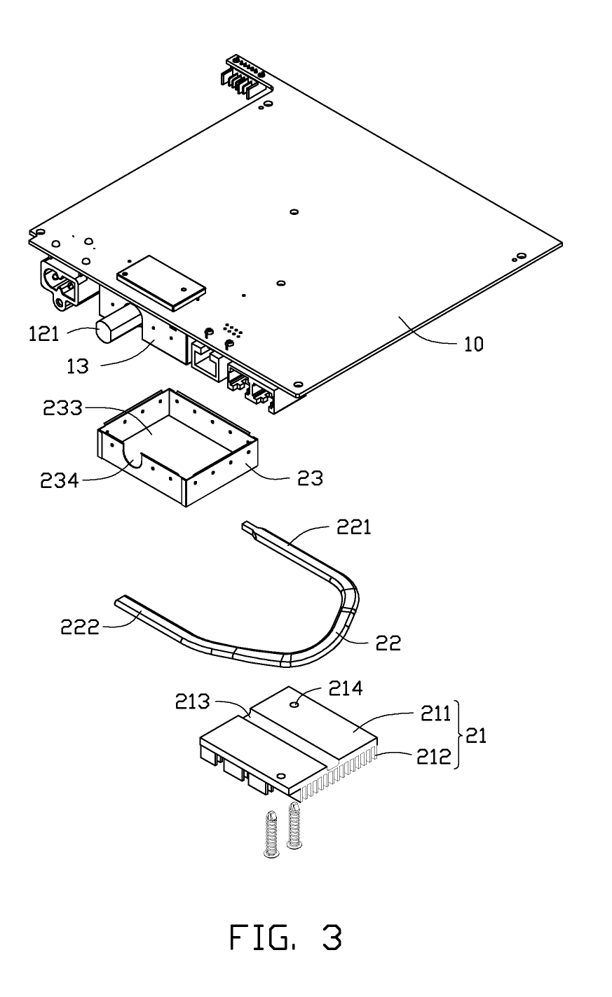

Referring also to FIG. 3, the thermal module 20 is used for dissipating heat generated by the heat-generating chip 11, and for shielding EMI radiation emitting from the EMI source 12. The thermal module 20 includes a heat sink 21, a heat conducting member 22, and a shielding cover 23. The heat sink 21 is attached on the heat-generating chip 11 for dissipating heat therefrom. The heat sink 21 includes a base 211, and a plurality of fins 212 formed on a top surface of the base 211. The base 211 defines two through holes 214 therein through which two fixing members 24 extend to mount the heat sink 21 on the heat-generating chip 11. The base 211 defines a groove 213 in a bottom surface thereof receiving a section of the heat conducting member 22.

One end of the heat conducting member 22 thermally connects with the heat-generating chip 11, and the other end of the heat conducting member 22 thermally connects with the shielding cover 23. Heat generated by the heat-generating chip 11 is transferred to the shielding cover 23 by the heat conducting member 22. In this embodiment, the heat conducting member 22 is a heat pipe. The heat pipe includes an evaporating section 221 and a condensing section 222. The evaporating section 221 is received in the groove 213 of the base 211 of the heat sink 21, and the condensing section 222 is attached on the shielding cover 23.

The shielding cover 23 includes a rectangular top plate 231, and a side plate 232 depending from a peripheral edge of the top plate 231. The top plate 231 and the side plate 232 cooperatively define a cavity 233 (see FIG. 3) therebetween. The shielding cover 23 covers the EMI source 12 in the cavity 233, and connects to the mounting seat 13 by the side plate 232. In other embodiments, the shielding cover 23 can be mounted on the circuit board 10 directly, whereby the mounting seat 13 can be omitted. The side plate 232 of the shielding cover 23 defines a cutout 234 therein, corresponding to the opening 122 of the mounting seat 13 through which the signal cable 121 extends. The shielding cover 23 is made of heat-conductive and electrically-conductive material such as metal. In particular, the metal may be copper, aluminum, steel, copper alloy or aluminum alloy. Thus, the shielding cover 23 is capable of dissipating heat and shielding EMI radiation.

In assembly, the evaporating section 221 of the heat pipe is attached on the heat-generating chip 11 and received in the groove 213 of the base 211 of the heat sink 21. The heat sink 21 and the evaporating section 221 of the heat pipe are mounted on the heat-generating chip 11 by the fixing members 24. The shielding cover 23 is disposed around the mounting seat 13 to cover the EMI source 12 in the cavity 233. The side plate 232 of the shielding cover 23 engages with the mounting seat 13 to mount the shielding cover 23 on the mounting seat 13. The condensing section 222 of the heat pipe is attached on an outer surface of the top plate 231 of the shielding cover 23.

In operation, a portion of heat generated by the heat-generating chip 11 is transferred to the fins 212 of the heat sink 21 via the base 211, and then dissipated by the fins 212. Another portion of the heat generated by the heat-generating chip 11 is transferred to the shielding cover 23 via the heat conducting member 22, and then dissipated by the shielding cover 23.

In the thermal module 20, the shielding cover 23 is capable of both dissipating heat from the heat-generating chip 11 and shielding EMI radiation emitting from the EMI source 12. There is no need to provide an additional heat dissipation member for dissipating heat transferred by the heat conducting member 22. The components of the thermal module 20 are saved. Thus, the electronic device 100 has more room for accommodating other components. The thermal module 20 is multifunctional and cost effective.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thermal module comprising:
a shielding cover made of heat-conductive and electrically-conductive material, the shielding cover defining a cavity therein for receiving an electromagnetic interference (EMI) source, the shielding cover being configured for enclosing the EMI source for EMI shielding; and
a heat conducting member having one end thermally connecting with the shielding cover and another end configuring for thermally connecting with a heat-generating chip.

2. The thermal module of claim 1, wherein the shielding cover is made of metal.

3. The thermal module of claim 1, wherein the shielding cover comprises a top plate and a side plate depending from a peripheral edge of the top plate, and the top plate and the side plate cooperatively define the cavity.

4. The thermal module of claim 1, further comprising a heat sink, the end of the heat conducting member for thermally connecting with the heat-generating chip being connected to the heat sink.

5. The thermal module of claim 4, wherein the heat conducting member comprises a heat pipe, the heat pipe having an evaporating section and a condensing section, the evaporating section of the heat pipe being connected to the heat sink, the condensing section of the heat pipe being connected to the shielding cover.

6. The thermal module of claim 5, wherein the heat sink comprises a base and a plurality of fins formed on a top surface of the base, the base defining a groove in a bottom surface thereof, the evaporating section of the heat pipe being received in the groove of the base of the heat sink.

7. The thermal module of claim 1, wherein the heat conducting member comprises a heat pipe, the heat pipe having an evaporating section and a condensing section, the evaporating section of the heat pipe being configured for thermally connecting with the heat-generating chip, the condensing section of the heat pipe being connected to the shielding cover.

8. An electronic device comprising:
a circuit board having a heat-generating chip and an electromagnetic interference (EMI) source mounted thereon; and
a thermal module mounted on the circuit board, the thermal module comprising:
a shielding cover made of heat-conductive and electrically-conductive material, the shielding cover defining a cavity therein, the shielding cover enclosing the EMI source in the cavity for EMI shielding; and
a heat conducting member having one end thermally connecting with the shielding cover and another end thermally connecting with the heat-generating chip for transferring heat from the heat-generating chip to the shielding cover.

9. The electronic device of claim 8, wherein the shielding cover is made of metal.

10. The electronic device of claim 8, wherein the shielding cover comprises a top plate and a side plate depending from a peripheral edge of the top plate, the top plate and the side plate cooperatively define the cavity.

11. The electronic device of claim 8, wherein the heat conducting member comprises a heat pipe, the heat pipe having an evaporating section and a condensing section, the evaporating section of the heat pipe thermally connecting with the heat-generating chip, the condensing section being connected to the shielding cover.

12. The electronic device of claim 11, wherein the thermal module further comprises a heat sink attached on the heat-generating chip, the evaporating section of the heat pipe being connected to the heat sink.

13. The electronic device of claim 12, wherein the heat sink comprises a base and a plurality of fins formed on a top surface of the base, the base defining a groove in a bottom surface of the base, the evaporating section of the heat pipe being received in the groove of the base of the heat sink.

14. The electronic device of claim 8, wherein the thermal module further comprises a heat sink attached on the heat-generating chip, the end of the heat conducting member for thermally connecting with the heat-generating chip being connected to the heat sink.

15. The electronic device of claim 8, wherein further comprising a mounting seat fixed on the circuit board and surrounding the EMI source, the shielding cover engaging with the mounting seat.

16. A thermal module comprising:
a shielding cover made of heat-conductive and electrically-conductive material, the shielding cover defining a cavity therein for receiving an electronic component, the shielding cover configured for enclosing the electronic component for electromagnetic interference (EMI) shielding; and
a heat-conductive member having one end thermally connecting with the shielding cover and another end configuring for thermally connecting with a heat-generating electronic component.
